(19) United States
(12) Patent Application Publication
(10) Pub. No.: US 2023/0068160 A1
(43) Pub. Date: Mar. 2, 2023

(54) PACKAGE CARRIER AND PACKAGE STRUCTURE

(71) Applicant: Subtron Technology Co., Ltd., Hsinchu County (TW)

(72) Inventors: Shaw-Wen Lao, Hsinchu County (TW); Chih-Peng Fan, Hsinchu County (TW); Ping-I Cheng, Hsinchu County (TW)

(73) Assignee: Subtron Technology Co., Ltd., Hsinchu County (TW)

(21) Appl. No.: 17/742,414

(22) Filed: May 12, 2022

(30) Foreign Application Priority Data
Aug. 25, 2021 (TW) 110131543

(51) Int. Cl. H01L 23/498; H01L 25/065; H01L 23/538

(52) U.S. Cl. CPC H01L 23/49822; H01L 23/49838; H01L 25/0652; H01L 23/5383; H01L 24/16

(57) ABSTRACT

A package carrier including a multi-layer circuit substrate and a silicon wafer is provided. The multi-layer circuit substrate has a first opening and a second opening communicating with each other. A first diameter and a first depth of the first opening are respectively greater than a second diameter and a second depth of the second opening. The silicon wafer is embedded in the first opening of the multi-layer circuit substrate. The silicon wafer has an active surface and includes a connecting circuit layer. The connecting circuit layer is disposed on the active surface and electrically connected to the multi-layer circuit substrate. The second opening of the multi-layer circuit substrate exposes part of the connecting circuit layer.

### CROSS-REFERENCE TO RELATED APPLICATION

This application claims the priority benefit of Taiwan application serial no. 110131543, filed on August 25, 2021. The entirety of the above-mentioned patent application is hereby incorporated by reference herein and made a part of this specification.

### BACKGROUND

### Technical Field

The invention relates to a substrate structure, and particularly relates to a package carrier and a package structure using the package carrier.

### Description of Related Art

With the thinning of electronic devices, a current trend is to directly connect heterogeneous semiconductor components to reduce the use of intermediate substrates. Accordingly, not only the size of a semiconductor package may be reduced, but also an electrical path may be shortened to improve the calculation speed of the semiconductor package. However, how to directly connect the heterogeneous semiconductor components has become an urgent problem to be solved at present.

### SUMMARY

The invention is directed to a package carrier, which meets a current trend of lightweight, thinness, and compactness through heterogeneous integration characteristics.

The invention is also directed to a package structure, which adopts the aforementioned package carrier to achieve a thinner package thickness, a better heat dissipation effect and better structural reliability.

The invention provides a package carrier including a multi-layer circuit substrate and a silicon wafer. The multi-layer circuit substrate has a first opening and a second opening communicating with each other. A first diameter and a first depth of the first opening are respectively greater than a second diameter and a second depth of the second opening. The silicon wafer is embedded in the first opening of the multi-layer circuit substrate. The silicon wafer has an active surface and includes a connecting circuit layer. The connecting circuit layer is disposed on the active surface and electrically connected to the multi-layer circuit substrate. The second opening of the multi-layer circuit substrate exposes part of the connecting circuit layer.

In an embodiment of the invention, the multi-layer circuit substrate includes a core dielectric layer, a first patterned circuit layer, a second patterned circuit layer, a first dielectric layer, a third patterned circuit layer, a second dielectric layer, a fourth patterned circuit layer, at least one first conducting via, at least one second conducting via, at least one third conducting via, and at least one fourth conducting via. The core dielectric layer has an upper surface and a lower surface opposite to each other. The first patterned circuit layer is disposed on the upper surface of the core dielectric layer. The second patterned circuit layer is disposed on the lower surface of the core dielectric layer. The first dielectric layer is disposed on the upper surface of the core dielectric layer and covers the first patterned circuit layer. The third patterned circuit layer is disposed on the first dielectric layer. The second dielectric layer is disposed on the lower surface of the core dielectric layer and covers the second patterned circuit layer. The fourth patterned circuit layer is disposed on the second dielectric layer. The first conducting via penetrates through the core dielectric layer and electrically connected to the first patterned circuit layer and the second patterned circuit layer. The second conducting via penetrates through the first dielectric layer and electrically connected to the third patterned circuit layer and the first patterned circuit layer. The third conducting via penetrates through the second dielectric layer and electrically connected to the fourth patterned circuit layer and the second patterned circuit layer. The fourth conducting via penetrates through the first dielectric layer and electrically connected to the third patterned circuit layer and the connecting circuit layer of the silicon wafer.

In an embodiment of the invention, the multi-layer circuit substrate further includes a first solder mask layer and a second solder mask layer. The first solder mask layer covers the first dielectric layer and the third patterned circuit layer. The first solder mask layer has a third opening and a plurality of first open pores. The third opening communicates with the second opening and the first opening, and a third diameter of the third opening is greater than or equal to the second diameter. The first open pores expose part of the third patterned circuit layer to define a plurality of first pads. The second solder mask layer covers the second dielectric layer and the fourth patterned circuit layer. The second solder mask layer has a plurality of second open pores, and the second open pores expose part of the fourth patterned circuit layer to define a plurality of second pads.

In an embodiment of the invention, the package carrier further includes a first surface treatment layer and a second surface treatment layer. The first surface treatment layer is disposed on the first pads. The second surface treatment layer is disposed on the second pads.

In an embodiment of the invention, the package carrier further includes an insulating material filled in the first opening of the multi-layer circuit substrate. The silicon wafer is fixed in the first opening through the insulating material.

The invention provides a package structure including a package carrier and at least one chip. The package carrier includes a multi-layer circuit substrate and a silicon wafer. The multi-layer circuit substrate has a first opening and a second opening communicating with each other. A first diameter and a first depth of the first opening are respectively greater than a second diameter and a second depth of the second opening. The silicon wafer is embedded in the first opening of the multi-layer circuit substrate. The silicon wafer has an active surface and includes a connecting circuit layer. The connecting circuit layer is disposed on the active surface and electrically connected to the multi-layer circuit substrate. The second opening of the multi-layer circuit substrate exposes part of the connecting circuit layer. The chip is disposed on the package carrier and is located in the second opening of the multi-layer circuit substrate, where the chip is electrically connected to the connecting circuit layer of the silicon wafer.

In an embodiment of the invention, the multi-layer circuit substrate includes a core dielectric layer, a first patterned circuit layer, a second patterned circuit layer, a first dielectric layer, a third patterned circuit layer, a second dielectric layer, a fourth patterned circuit layer, at least one first conducting via, at least one second conducting via, at least one third conducting via, and at least one fourth conducting via. The core dielectric layer has an upper surface and a lower surface opposite to each other. The first patterned circuit layer is disposed on the upper surface of the core dielectric layer. The second patterned circuit layer is disposed on the lower surface of the core dielectric layer. The first dielectric layer is disposed on the upper surface of the core dielectric layer and covers the first patterned circuit layer. The third patterned circuit layer is disposed on the first dielectric layer. The second dielectric layer is disposed on the lower surface of the core dielectric layer and covers the second patterned circuit layer. The fourth patterned circuit layer is disposed on the second dielectric layer. The first conducting via penetrates through the core dielectric layer and electrically connected to the first patterned circuit layer and the second patterned circuit layer. The second conducting via penetrates through the first dielectric layer and electrically connected to the third patterned circuit layer and the first patterned circuit layer. The third conducting via penetrates through the second dielectric layer and electrically connected to the fourth patterned circuit layer and the second patterned circuit layer. The fourth conducting via penetrates through the first dielectric layer and electrically connected to the third patterned circuit layer and the connecting circuit layer of the silicon wafer.

In an embodiment of the invention, the multi-layer circuit substrate further includes a first solder mask layer and a second solder mask layer. The first solder mask layer covers the first dielectric layer and the third patterned circuit layer. The first solder mask layer has a third opening and a plurality of first open pores. The third opening communicates with the second opening and the first opening, and a third diameter of the third opening is greater than or equal to the second diameter. The first open pores expose part of the third patterned circuit layer to define a plurality of first pads. The second solder mask layer covers the second dielectric layer and the fourth patterned circuit layer. The second solder mask layer has a plurality of second open pores, and the second open pores expose part of the fourth patterned circuit layer to define a plurality of second pads.

In an embodiment of the invention, the package carrier further includes a first surface treatment layer and a second surface treatment layer. The first surface treatment layer is disposed on the first pads. The second surface treatment layer is disposed on the second pads.

In an embodiment of the invention, the package carrier further includes an insulating material filled in the first opening of the multi-layer circuit substrate. The silicon wafer is fixed in the first opening through the insulating material.

In an embodiment of the invention, the at least one chip includes a first chip and a second chip. The first chip is electrically connected to the connecting circuit layer of the silicon wafer in a flip-chip manner, and the second chip is electrically connected to the third patterned circuit layer in a wire bonding manner.

In an embodiment of the invention, the package structure further includes a package body and an optical fiber. The package body is disposed in the second opening of the multi-layer circuit substrate and is electrically connected to the connecting circuit layer of the silicon wafer. The package body and the chip are electrically connected through the connecting circuit layer. The optical fiber is disposed on the multi-layer circuit substrate, the optical fiber and the package body are located on the same side of the multi-layer circuit substrate, and the package body is electrically connected to the optical fiber.

In an embodiment of the invention, the chip includes a first chip and a second chip. The first chip and the second chip are respectively electrically connected to the connecting circuit layer of the silicon wafer in a flip-chip manner. The first chip and the second chip are electrically connected through the connecting circuit layer.

In summary, in the design of the package carrier of the invention, the silicon wafer is embedded in the first opening of the multi-layer circuit substrate, the second opening of the multi-layer circuit substrate exposes the connecting circuit layer of the silicon wafer, and the connecting circuit layer is electrically connected to the multi-layer circuit substrate. In this way, the package carrier of the invention may achieve an effect of heterogeneous integration and may meet the current trend of lightweight, thinness, and compactness. In addition, regarding the package structure using the package carrier of the invention, the chip is disposed in the second opening of the multi-layer circuit substrate and electrically connected to the connecting circuit layer of the silicon wafer, the silicon wafer may transmit signals through electric conduction, a material thereof has a heat dissipation effect, and a thermal expansion coefficient thereof is similar to that of the chip, so the package structure of the invention has both a thinner package thickness and a good heat dissipation effect as well as structural reliability.

To make the aforementioned more comprehensible, several embodiments accompanied with drawings are described in detail as follows.

### BRIEF DESCRIPTION OF THE DRAWINGS

The accompanying drawings are included to provide a further understanding of the invention and are incorporated in and constitute a part of this specification. The drawings illustrate embodiments of the invention and, together with the description, serve to explain the principles of the invention.

FIG. 1 is a schematic cross-sectional view of a package carrier according to an embodiment of the invention.

FIG. 2 is a schematic cross-sectional view of a package structure according to an embodiment of the invention.

FIG. 3 is a schematic cross-sectional view of a package structure according to another embodiment of the invention.

FIG. 4 is a schematic cross-sectional view of a package structure according to another embodiment of the invention.

### DESCRIPTION OF THE EMBODIMENTS

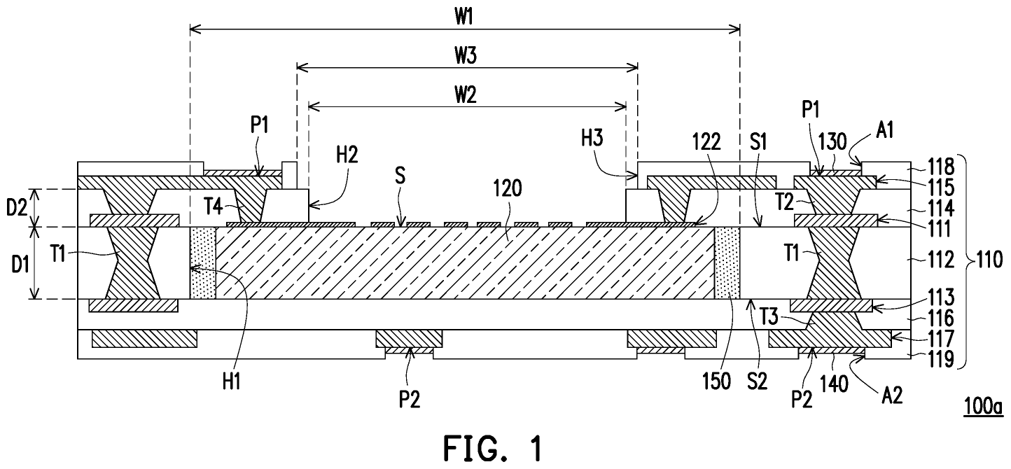

FIG. 1 is a schematic cross-sectional view of a package carrier according to an embodiment of the invention. Referring to FIG. 1, in the embodiment, a package carrier 100a includes a multi-layer circuit substrate 110 and a silicon wafer 120. The multi-layer circuit substrate 110 has a first opening H1 and a second opening H2 communicating with each other.

A first diameter W1 and a first depth D1 of the first opening H1 are respectively greater than a second diameter W2 and a second depth D2 of the second opening H2. The silicon wafer 120 is embedded in the first opening H1 of the multi-layer circuit substrate 110. The silicon wafer 120 has an active surface S and includes a connecting circuit layer 122. The connecting circuit layer 122 is disposed on the active surface S and is electrically connected to the multi=layer circuit substrate 110. The second opening H2 of the multi-layer circuit substrate 110 exposes part of the connecting circuit layer 122.

In detail, the multi-layer circuit substrate 110 of the embodiment includes a core dielectric layer 112, a first patterned circuit layer 111, a second patterned circuit layer 113, a first dielectric layer 114, and a third patterned circuit layer 115, a second dielectric layer 116, a fourth patterned circuit layer 117, at least one first conducting via T1, at least one second conducting via T2, at least one third conducting via T3, and at least one fourth conducting via T4. The core dielectric layer 112 has an upper surface S1 and a lower surface S2 opposite to each other. The first patterned circuit layer 111 is disposed on the upper surface Si of the core dielectric layer 112. The second patterned circuit layer 113 is disposed on the lower surface S2 of the core dielectric layer 112. The first dielectric layer 114 is disposed on the upper surface Si of the core dielectric layer 112 and covers the first patterned circuit layer 111. The third patterned circuit layer 115 is disposed on the first dielectric layer 114. The second dielectric layer 116 is disposed on the lower surface S2 of the core dielectric layer 112, and covers the second patterned circuit layer 113. The fourth patterned circuit layer 117 is disposed on the second dielectric layer 116. The first conducting via T1 penetrates through the core dielectric layer 112 and electrically connects the first patterned circuit layer 111 and the second patterned circuit layer 113. The second conducting via T2 penetrates through the first dielectric layer 114 and electrically connects the third patterned circuit layer 115 and the first patterned circuit layer 111. The third conducting via T3 penetrates through the second dielectric layer 116 and electrically connects the fourth patterned circuit layer 117 and the second patterned circuit layer 113. The fourth conducting via T4 penetrates through the first dielectric layer 114 and electrically connects the third patterned circuit layer 115 and the connecting circuit layer 122 of the silicon wafer 120. In brief, the multi-layer circuit substrate 110 of the embodiment is embodied as a four-layer circuit substrate, but it is only an example, and the invention is not limited to the four-layer circuit substrate.

In addition, the multi-layer circuit substrate 110 of the embodiment further includes a first solder mask layer 118 and a second solder mask layer 119. The first solder mask layer 118 covers the first dielectric layer 114 and the third patterned circuit layer 115. The first solder mask layer 118 has a third opening H3 and a plurality of first open pores A1. The third opening H3 communicates with the second opening H2 and the first opening H1, and a third diameter W3 of the third opening H3 is greater than the second diameter W2. The first open pores Al expose part of the third patterned circuit layer 115 to define a plurality of first pads P1. The second solder mask layer 119 covers the second dielectric layer 116 and the fourth patterned circuit layer 117. The second solder mask layer 119 has a plurality of second open pores A2, and the second open pores A2 expose part of the fourth patterned circuit layer 117 to define a plurality of second pads P2.

In order to prevent oxidation of the first pad P1 and the second pad P2, the package carrier 100a of the embodiment further includes a first surface treatment layer 130 and a second surface treatment layer 140. The first surface treatment layer 130 is disposed on the first pad P1, and the second surface treatment layer 140 is disposed on the second pad P2. The first surface treatment layer 130 and the second surface treatment layer 140 are, for example, respectively a nickel layer, a gold layer, a silver layer or a nickel-palladium-gold layer, but the invention is not limited thereto. The arrangement of the first surface treatment layer 130 and the second surface treatment layer 140 may not only avoid oxidation of the first pad P1 and the second pad P2 but may also make wires to be easily electrically connected with the first pad P1 and the second pad P2 in the subsequent electrical connection with the chip through wire bonding.

In addition, the package carrier 100a of the embodiment further includes an insulating material 150 filled in the first opening H1 of the multi-layer circuit substrate 110. The silicon wafer 120 is fixed in the first opening H1 through the insulating material 150, where the insulating material 150 is, for example, hole plugging resin. Namely, when the silicon wafer 120 is embedded in the first opening H1 of the multi-layer circuit substrate 110, there is a gap between the silicon wafer 120 and an inner wall of the first opening H1, and the insulating material 150 may be filled in the gap and located between the silicon wafer 120 and the first opening H1 to fix and position the silicon wafer 120. Preferably, a top view shape of the first opening H1 is a rounded rectangle.

Moreover, a thickness of the silicon wafer 120 of the embodiment is approximately equal to a thickness of the core dielectric layer 112 (i.e., the first depth D1). When the silicon wafer 120 is embedded in the first opening H1 of the multi-layer circuit substrate 110, preferably, the active surface S of the silicon wafer 120 is aligned with the upper surface Si of the core dielectric layer 112, and a bottom surface of the silicon wafer 120 is aligned with the lower surface S2, which may effectively reduce an overall package thickness of the subsequent chip package. Moreover, the second opening H2 of the multi-layer circuit substrate 110 only exposes part of the connecting circuit layer 122 of the silicon wafer 120, which means that part of the connecting circuit layer 122 is covered by the first dielectric layer 114, and the connecting circuit layer 122 exposed outside the first dielectric layer 114 may be directly electrically connected to an electronic element, subsequently.

In brief, since the silicon wafer 120 of this embodiment is embedded in the first opening H1 of the multi-layer circuit substrate 110, and the second opening H2 of the multi-layer circuit substrate 110 exposes the connecting circuit layer 122 of the silicon wafer 120, and the connecting circuit layer 122 is electrically connected to the third patterned circuit layer 115 of the multi-layer circuit substrate 110 through the fourth conducting via T4. In this way, the package carrier 100a of the embodiment may achieve the effect of heterogeneous integration and may meet the current trend of lightweight, thinness, and compactness.

It should be noticed that reference numbers of the components and part of contents of the aforementioned embodiment are also used in the following embodiment, where the same reference numbers denote the same or like components, and descriptions of the same technical contents are omitted. The aforementioned embodiment may be referred for descriptions of the omitted parts, and detailed descriptions thereof are not repeated in the following embodiment.

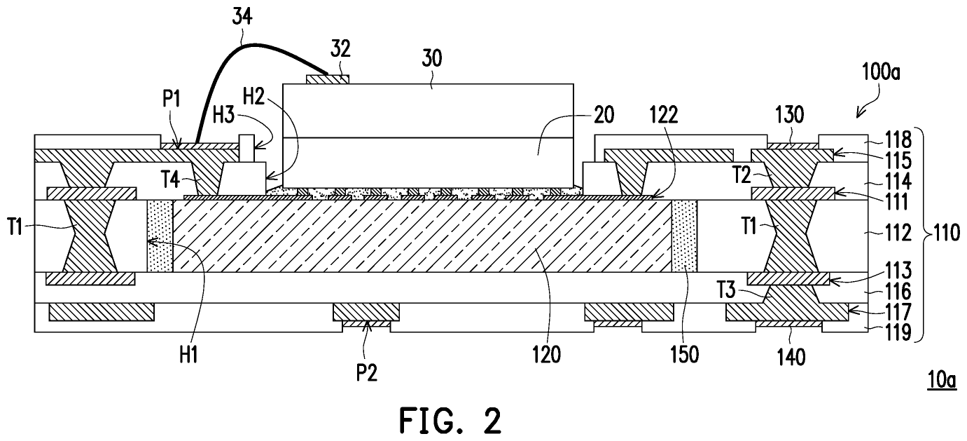

FIG. 2 is a schematic cross-sectional view of a package structure according to an embodiment of the invention. Referring to FIG. 2, in the embodiment, the package structure 10a includes the package carrier 100a and at least one chip. The at least one chip includes a first chip 20 and a second chip 30. The first chip 20 and the second chip 30 are disposed on the package carrier 100a, the first chip 20 is located in the second opening H2 of the multi-layer circuit substrate 110, and the second chip 30 is stacked on the first chip 20. The first chip 20 is electrically connected to the connecting circuit layer 122 of the silicon wafer 120 in the flip-chip manner, and the second chip 30 is electrically connected to the third patterned circuit layer 115 in a wire bonding manner. Namely, a wire 34 is electrically connected between an electrode 32 of the second chip 30 and the first pad P1.

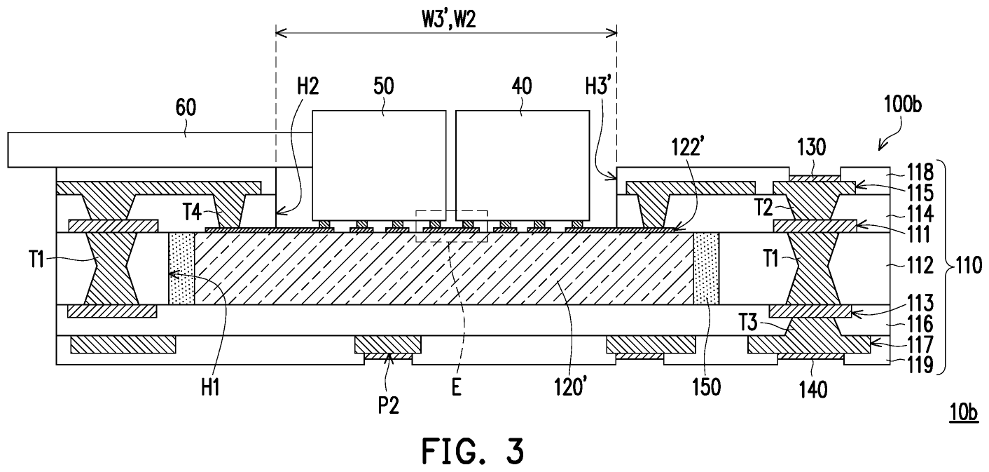

FIG. 3 is a schematic cross-sectional view of a package structure according to another embodiment of the invention. Referring to FIG. 2 and FIG. 3 at the same time, a package structure 10b of the embodiment is similar to the aforementioned package structure 10a, and differences there between are that in this embodiment, the package structure 10b only includes one chip 40, and the package structure 10b further includes a package body 50 and an optical fiber 60. In detail, the chip 40 is located in the second opening H2 of the multi-layer circuit substrate 110 and electrically connected to a connecting circuit layer 122′ of a silicon wafer 120′ in the flip-chip manner. The package body 50 is disposed in the second opening H2 of the multi-layer circuit substrate 110 and electrically connected to the connecting circuit layer 122′ of the silicon wafer 120′ in the flip-chip manner. The package body 50 and the chip 40 are electrically connected through the connecting circuit layer 122′ (referring to a region E in FIG. 3). The optical fiber 60 is disposed on the first solder mask layer 118 of the multi-layer circuit substrate 110 and located on the same side of the multi-layer circuit substrate 110 as the package body 50, where the package body 50 and the optical fiber 60 are electrically connected to serve as a switch. In addition, in the package carrier 100b of the embodiment, a third diameter W3′ of a third opening H3′ of the first solder mask layer 118 is equal to the second diameter W2 of the second opening H2 of the first dielectric layer 114.

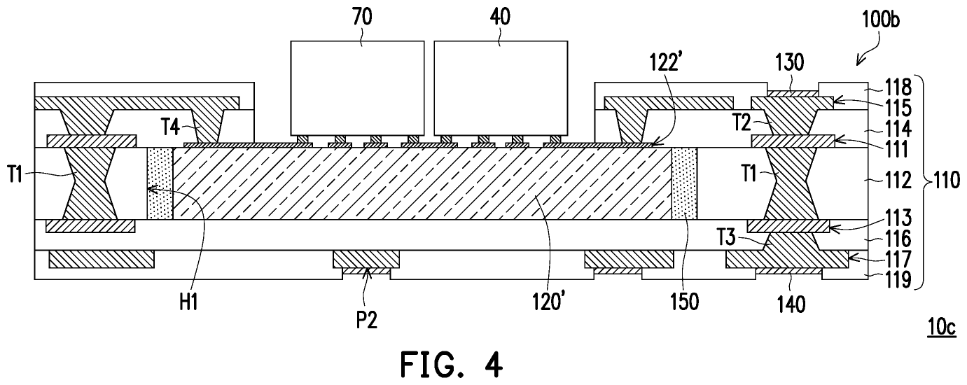

FIG. 4 is a schematic cross-sectional view of a package structure according to another embodiment of the invention. Referring to FIG. 3 and FIG. 4 at the same time, a package structure 10c of the embodiment is similar to the aforementioned package structure 10b, and differences there between are that in this embodiment, the package structure 10c includes two chips 40, 70, where the chips 40, 70 are respectively electrically connected to the connecting circuit layer 122′ of the silicon wafer 120′ in the flip-chip manner, and the chips 40, 70 are electrically connected through the connecting circuit layer 122′.

In brief, in the embodiment, the first chip 20, the chip 40, the package body 50, and the chip 70 are directly electrically connected to the connecting circuit layers 122, 122′ of the silicon wafers 120, 120′, where besides that the silicon wafers 120, 120′ may transmit signals through electric conduction, and materials thereof have a heat dissipation effect and thermal expansion coefficients thereof are similar to that of the chip. Therefore, the package structures 10a, 10b and 10c of the invention not only have a thinner package thickness, but also have a better heat dissipation effect and structural reliability.

In summary, in the design of the package carrier of the invention, the silicon wafer is embedded in the first opening of the multi-layer circuit substrate, the second opening of the multi-layer circuit substrate exposes the connecting circuit layer of the silicon wafer, and the connecting circuit layer is electrically connected to the multi-layer circuit substrate. In this way, the package carrier of the invention may achieve an effect of heterogeneous integration and may meet the current trend of lightweight, thinness, and compactness. In addition, regarding the package structure using the package carrier of the invention, the chip is disposed in the second opening of the multi-layer circuit substrate and electrically connected to the connecting circuit layer of the silicon wafer, the silicon wafer may transmit signals through electric conduction, a material thereof has a heat dissipation effect, and a thermal expansion coefficient thereof is similar to that of the chip, so the package structure of the invention has both a thinner package thickness and a good heat dissipation effect as well as structural reliability.

It will be apparent to those skilled in the art that various modifications and variations can be made to the disclosed embodiments without departing from the scope or spirit of the invention. In view of the foregoing, it is intended that the invention covers modifications and variations provided they fall within the scope of the following claims and their equivalents.

What is claimed is:

1. A package carrier, comprising:
a multi-layer circuit substrate, having a first opening and a second opening communicating with each other, wherein a first diameter and a first depth of the first opening are respectively greater than a second diameter and a second depth of the second opening; and
a silicon wafer, embedded in the first opening of the multi-layer circuit substrate, having an active surface, and comprising a connecting circuit layer, wherein the connecting circuit layer is disposed on the active surface and electrically connected to the multi-layer circuit substrate, and the second opening of the multi-layer circuit substrate exposes part of the connecting circuit layer.

2. The package carrier as claimed in claim 1, wherein the multi-layer circuit substrate comprises:
a core dielectric layer, comprising an upper surface and a lower surface opposite to each other;
a first patterned circuit layer, disposed on the upper surface of the core dielectric layer;
a second patterned circuit layer, disposed on the lower surface of the core dielectric layer;
a first dielectric layer, disposed on the upper surface of the core dielectric layer and covering the first patterned circuit layer;
a third patterned circuit layer, disposed on the first dielectric layer;
a second dielectric layer, disposed on the lower surface of the core dielectric layer and covering the second patterned circuit layer;
a fourth patterned circuit layer, disposed on the second dielectric layer;
at least one first conducting via, penetrating through the core dielectric layer and electrically connected to the first patterned circuit layer and the second patterned circuit layer;
at least one second conducting via, penetrating through the first dielectric layer and electrically connected to the third patterned circuit layer and the first patterned circuit layer;
at least one third conducting via, penetrating through the second dielectric layer and electrically connected to the fourth patterned circuit layer and the second patterned circuit layer; and
at least one fourth conducting via, penetrating through the first dielectric layer and electrically connected to the third patterned circuit layer and the connecting circuit layer of the silicon wafer.

3. The package carrier as claimed in claim 2, wherein the multi-layer circuit substrate further comprises:
a first solder mask layer, covering the first dielectric layer and the third patterned circuit layer and comprising a third opening and a plurality of first open pores, wherein the third opening communicates with the second opening and the first opening, a third diameter of the third opening is greater than or equal to the second diameter, and the first open pores expose part of the third patterned circuit layer to define a plurality of first pads; and
a second solder mask layer, covering the second dielectric layer and the fourth patterned circuit layer and comprising a plurality of second open pores, wherein the second open pores expose part of the fourth patterned circuit layer to define a plurality of second pads.

4. The package carrier as claimed in claim 3, further comprising:
a first surface treatment layer, disposed on the first pads; and
a second surface treatment layer, disposed on the second pads.

5. The package carrier as claimed in claim 1, further comprising:
an insulating material, filled in the first opening of the multi-layer circuit substrate, wherein the silicon wafer is fixed in the first opening through the insulating material.

6. A package structure, comprising:
a package carrier, comprising:
a multi-layer circuit substrate, comprising a first opening and a second opening communicating with each other, wherein a first diameter and a first depth of the first opening are respectively greater than a second diameter and a second depth of the second opening; and
a silicon wafer, embedded in the first opening of the multi-layer circuit substrate, having an active surface, and comprising a connecting circuit layer, wherein the connecting circuit layer is disposed on the active surface and electrically connected to the multi-layer circuit substrate, and the second opening of the multi-layer circuit substrate exposes part of the connecting circuit layer;
at least one chip, disposed on the package carrier and located in the second opening of the multi-layer circuit substrate, wherein the at least one chip is electrically connected to the connecting circuit layer of the silicon wafer.

7. The package structure as claimed in claim 6, wherein the multi-layer circuit substrate comprises:
a core dielectric layer, comprising an upper surface and a lower surface opposite to each other;
a first patterned circuit layer, disposed on the upper surface of the core dielectric layer;
a second patterned circuit layer, disposed on the lower surface of the core dielectric layer;
a first dielectric layer, disposed on the upper surface of the core dielectric layer and covering the first patterned circuit layer;
a third patterned circuit layer, disposed on the first dielectric layer;
a second dielectric layer, disposed on the lower surface of the core dielectric layer and covering the second patterned circuit layer;
a fourth patterned circuit layer, disposed on the second dielectric layer;
at least one first conducting via, penetrating through the core dielectric layer and electrically connected to the first patterned circuit layer and the second patterned circuit layer;
at least one second conducting via, penetrating through the first dielectric layer and electrically connected to the third patterned circuit layer and the first patterned circuit layer;
at least one third conducting via, penetrating through the second dielectric layer and electrically connected to the fourth patterned circuit layer and the second patterned circuit layer; and
at least one fourth conducting via, penetrating through the first dielectric layer and electrically connected to the third patterned circuit layer and the connecting circuit layer of the silicon wafer.

8. The package structure as claimed in claim 7, wherein the multi-layer circuit substrate further comprises:
a first solder mask layer, covering the first dielectric layer and the third patterned circuit layer and comprising a third opening and a plurality of first open pores, wherein the third opening communicates with the second opening and the first opening, a third diameter of the third opening is greater than or equal to the second diameter, and the first open pores expose part of the third patterned circuit layer to define a plurality of first pads; and
a second solder mask layer, covering the second dielectric layer and the fourth patterned circuit layer, and having a plurality of second open pores, wherein the second open pores expose part of the fourth patterned circuit layer to define a plurality of second pads.

9. The package structure as claimed in claim 8, wherein the package carrier further comprises:
a first surface treatment layer, disposed on the first pads; and
a second surface treatment layer, disposed on the second pads.

10. The package structure as claimed in claim 6, wherein the package carrier further comprises:
an insulating material, filled in the first opening of the multi-layer circuit substrate, wherein the silicon wafer is fixed in the first opening through the insulating material.

11. The package structure as claimed in claim 6, wherein the at least one chip comprises a first chip and a second chip, the first chip is electrically connected to the connecting circuit layer of the silicon wafer in a flip-chip manner, and the second chip is electrically connected to the third patterned circuit layer in a wire bonding manner.

12. The package structure as claimed in claim 6, further comprising:
a package body, disposed in the second opening of the multi-layer circuit substrate and electrically connected to the connecting circuit layer of the silicon wafer, wherein the package body and the at least one chip are electrically connected through the connecting circuit layer; and
an optical fiber, disposed on the multi-layer circuit substrate, wherein the optical fiber and the package body are located on a same side of the multi-layer circuit substrate, and the package body is electrically connected to the optical fiber.

13. The package structure as claimed in claim 6, wherein the at least one chip comprises a first chip and a second chip, the first chip and the second chip are respectively electrically connected to the connecting circuit layer of the silicon wafer in a flip-chip manner, and the first chip and the second chip are electrically connected through the connecting circuit layer.
